(19) United States
(12) Patent Application Publication
(10) Pub. No.: US 2011/0053301 A1
(43) Pub. Date: Mar. 3, 2011

(54) THIN FILM DEPOSITION APPARATUS AND METHOD OF MANUFACTURING ORGANIC LIGHT-EMITTING DISPLAY DEVICE BY USING THE SAME

(75) Inventors: Hee-Cheol KANG, Yongin-City (KR); Jong-Heon Kim, Yongin-City (KR); Ji-Sook Oh, Yongin-City (KR); Sang-Soo Kim, Yongin-City (KR)

(73) Assignee: Samsung Mobile Display Co., Ltd., Yongin-City (KR)

(21) Appl. No.: 12/868,099

(22) Filed: Aug. 25, 2010

(30) Foreign Application Priority Data
Aug. 27, 2009 (KR) 10-2009-0079768
Feb. 8, 2010 (KR) 10-2010-0011481

(51) Int. Cl. H01L 51/30

(52) U.S. Cl. 438/34; 118/728; 118/720; 257/E51.025

(57) ABSTRACT

A thin film deposition apparatus that is suitable for production of large-sized substrates with fine patterns includes: an electrostatic chuck including a body that contacts a substrate that constitutes a deposition target and including a supporting surface supporting the substrate, an electrode installed in the body to generate an electrostatic force on the supporting surface, and a battery that is electrically connected to the electrode in the body; a plurality of chambers that are maintained in vacuum states; at least one thin film deposition assembly disposed in one of the plurality of chambers, separated by a predetermined distance from the substrate, and forming a thin film on the substrate supported by the electrostatic chuck; and a carrier moving the electrostatic chuck through the chambers.

### CROSS-REFERENCE TO RELATED APPLICATIONS

This application claims the benefit of Korean Application No(s). 10-2009-0079768, filed Aug. 27, 2009 and 10-2010-0011481 filed Feb. 8, 2010, in the Korean Intellectual Property Office, the disclosures of which are incorporated herein by reference.

### BACKGROUND OF THE INVENTION

1. Field of the Invention

Aspects of the present invention relate to a thin film deposition apparatus and a method of manufacturing an organic light-emitting display device by using the same, and more particularly, to a thin film deposition apparatus that can be simply applied to the manufacture of large-sized display devices on a mass scale, and a method of manufacturing an organic light-emitting display device by using the thin film deposition apparatus.

2. Description of the Related Art

Organic light-emitting display devices have a larger viewing angle, better contrast characteristics, and a faster response rate than other display devices, and thus have drawn attention as a next-generation display device.

An organic light-emitting display device includes intermediate layers, including an emission layer disposed between a first electrode and a second electrode that are arranged opposite to each other. The electrodes and the intermediate layers may be formed via various methods, one of which is a deposition method. When an organic light-emitting display device is manufactured by using the deposition method, a fine metal mask (FMM) having the same pattern as a thin film to be formed is disposed to closely contact a substrate, and a thin film material is deposited over the FMM in order to form the thin film having the desired pattern.

However, the deposition method using such an FMM presents problems in manufacturing larger devices using a mother glass having a large size. In more detail, when a large mask is used in a deposition onto a large mother glass, the mask may bend due to self-gravity, thereby distorting a pattern. Such pattern distortion is not conducive for the recent trend towards high-definition patterns.

On the other hand, according to the conventional deposition method, a metal mask is placed on a surface of a substrate and a magnet is disposed on the other surface of the substrate in a state where edges of the substrate are fixed by an additional chuck, and thus, the metal mask may be adhered onto the surface of the substrate by the magnet. However, in the above deposition method, since the edges of the substrate are only supported, a center portion of the substrate may sag when the substrate has a large area. This sagging of the substrate becomes more severe as the substrate increases in size.

### SUMMARY OF THE INVENTION

In order to address at least the drawbacks of the deposition method using a fine metal mask (FMM) and/or other issues, aspects of the present invention provide a thin film deposition apparatus that may be simply applied to produce large-sized display devices on a mass scale and that may be suitable for high-definition patterning, and a method of manufacturing an organic light-emitting display device by using the thin film deposition apparatus.

According to an aspect of the present invention, there is provided a thin film deposition apparatus including: an electrostatic chuck comprising a body that contacts a substrate that constitutes a deposition target and that includes a supporting surface that fixedly engages the substrate by an electrostatic force, an electrode installed in the body to generate the electrostatic force on the supporting surface, and a battery that is electrically connected to the electrode in the body; a plurality of chambers that are maintained in vacuum states; at least one thin film deposition assembly disposed in one of the plurality of chambers, separated by a predetermined distance from the substrate, and forming a thin film on the substrate supported by the electrostatic chuck; and a carrier that moves the electrostatic chuck through the chambers.

According to a non-limiting aspect, the battery may be formed in the body.

According to a non-limiting aspect, the carrier may include: a support that extends through the chambers; a movement bar that engages the support and that supports edges of the electrostatic chuck; and a driving unit disposed between the support and the movement bar to move the movement bar along the support.

According to a non-limiting aspect, the thin film deposition assembly may include: a deposition source that discharges a deposition material; a deposition source nozzle unit disposed at a side of the deposition source and including a plurality of deposition source nozzles arranged in a first direction; and a patterning slit sheet disposed opposite to and spaced apart from the deposition source nozzle unit and including a plurality of patterning slits arranged in a second direction perpendicular to the first direction, wherein deposition may be performed while the substrate or the thin film deposition assembly is moved relative to the other in the first direction, and the deposition source, the deposition source nozzle unit, and the patterning slit sheet may be integrally formed as one body.

According to a non-limiting aspect, the deposition source and the deposition source nozzle unit, and the patterning slit sheet may be integrally connected as one body by a connection member that guides flow of the deposition material.

According to a non-limiting aspect, the connection member may seal a space between the deposition source nozzle unit disposed at the side of the deposition source, and the patterning slit sheet.

According to a non-limiting aspect, the plurality of deposition source nozzles may be tilted at a predetermined angle.

According to a non-limiting aspect, the plurality of deposition source nozzles may include deposition source nozzles arranged in two rows disposed in the first direction, and the each of the deposition source nozzles in each of the two rows may be tilted at the predetermined angle toward a corresponding deposition source nozzle of the other of the two rows.

According to a non-limiting aspect, the plurality of deposition source nozzles may include deposition source nozzles arranged in two rows disposed in the first direction, the deposition source nozzles of a row located at a first side of the patterning slit sheet may be arranged to face a second side of the patterning slit sheet, and the deposition source nozzles of the other row located at the second side of the patterning slit sheet may be arranged to face the first side of the patterning slit sheet.

According to a non-limiting aspect, the thin film deposition assembly may include: a deposition source that discharges a deposition material; a deposition source nozzle unit disposed at a side of the deposition source and including a plurality of deposition source nozzles arranged in a first direction; a patterning slit sheet disposed opposite to the deposition source nozzle unit and including a plurality of patterning slits arranged in the first direction; and a barrier plate assembly comprising a plurality of barrier plates that are disposed between the deposition source nozzle unit and the patterning slit sheet in the first direction, and partition a space between the deposition source nozzle unit and the patterning slit sheet into a plurality of sub-deposition spaces, wherein the thin film deposition assembly may be spaced apart from the substrate, and the thin film deposition assembly or the substrate fixedly engaged onto the electrostatic chuck may be moved relative to the other.

According to a non-limiting aspect, the plurality of barrier plates may extend in a second direction substantially perpendicular to the first direction.

According to a non-limiting aspect, the barrier plate assembly may include a first barrier plate assembly including a plurality of first barrier plates, and a second barrier plate assembly including a plurality of second barrier plates.

According to a non-limiting aspect, each of the first barrier plates and each of the second barrier plates may extend in a second direction substantially perpendicular to the first direction.

According to a non-limiting aspect, the first barrier plates may be arranged to respectively correspond to the second barrier plates.

According to a non-limiting aspect, the deposition source and the barrier plate assembly may be spaced apart from each other.

According to a non-limiting aspect, the barrier plate assembly and the patterning slit sheet may be space apart from each other.

According to another aspect of the present invention, there is provided a method of manufacturing an organic light emitting display device, the method including: fixing a substrate that constitutes a deposition target onto an electrostatic chuck, wherein the electrostatic chuck comprises a body that contacts the substrate and that includes a supporting surface that fixedly engages the substrate by an electrostatic force, an electrode installed in the body to generate the electrostatic force on the supporting surface, and a battery that is electrically connected to the electrode in the body; transferring the electrostatic chuck on which the substrate is fixedly engaged through a plurality of chambers that are maintained in a vacuum state; and forming an organic layer on the substrate by depositing a deposition material from a thin film deposition assembly disposed in at least one of the chambers wherein the electrostatic chuck on which the substrate is disposed or the thin film deposition assembly is moved relative to the other.

According to a non-limiting aspect, the battery may be formed in the body.

According to a non-limiting aspect, the thin film deposition assembly may include: a deposition source that discharges the deposition material; a deposition source nozzle unit disposed at a side of the deposition source and including a plurality of deposition source nozzles arranged in a first direction; and a patterning slit sheet disposed opposite to and spaced apart from the deposition source nozzle unit and including a plurality of patterning slits arranged in a second direction perpendicular to the first direction, wherein the deposition source, the deposition source nozzle unit, and the patterning slit sheet may be integrally formed as one body, and the thin film deposition assembly may be spaced apart from the substrate, and the depositing of the deposition material may be performed while the substrate or the thin film deposition assembly is moved relative to the other in the first direction.

According to a non-limiting aspect, the thin film deposition assembly may include: a deposition source that discharges the deposition material; a deposition source nozzle unit disposed at a side of the deposition source and including a plurality of deposition source nozzles arranged in a first direction; a patterning slit sheet disposed opposite to and spaced apart from the deposition source nozzle unit and including a plurality of patterning slits arranged in the first direction; and a barrier plate assembly comprising a plurality of barrier plates that are disposed between the deposition source nozzle unit and the patterning slit sheet in the first direction, and that partition a space between the deposition source nozzle unit and the patterning slit sheet into a plurality of sub-deposition spaces, wherein the thin film deposition assembly may be separated from the substrate, and the depositing of the deposition material may be performed while the substrate or the thin film deposition assembly is moved relative to the other.

According to another embodiment of the present invention, there is provided a thin film deposition apparatus including a loading unit that fixes a substrate on which a deposition material is to be deposited onto an electrostatic chuck, wherein the electrostatic chuck includes a body that contacts the substrate and that includes a supporting surface that fixedly engages the substrate by an electrostatic force, an electrode installed in the body to generate the electrostatic force on the supporting surface, and a battery that is electrically connected to the electrode in the body; a deposition unit including one or more chambers and at least one thin film deposition assembly disposed in the one or more chambers to deposit a deposition material on the substrate fixed on the electrostatic chuck; an unloading unit that removes the substrate on which deposition has been performed from the electrostatic chuck; a first circulating unit including a first carrier that sequentially moves the electrostatic chuck from the loading unit through the one or more chambers of the deposition unit, and from the deposition unit to the unloading unit; and a second circulating unit including a second carrier that returns the electrostatic chuck from which the substrate has been removed by the unloading unit, to the loading unit.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic view of a thin film deposition apparatus according to an embodiment of the present invention;

FIG. 2 illustrates a modified example of the thin film deposition apparatus of FIG. 1;

FIG. 3 is a schematic view of an electrostatic chuck according to an embodiment of the present invention;

FIG. 4 is a schematic view of an electrostatic chuck according to another embodiment of the present invention;

FIG. 5 is a cross-sectional view of a first circular unit according to an embodiment of the present invention;

FIG. 6 is a cross-sectional view of a second circular unit according to an embodiment of the present invention;

FIG. 7 is a perspective view of a thin film deposition assembly according to an embodiment of the present invention;

FIG. 8 is a schematic cross-sectional side view of the thin film deposition assembly of FIG. 7, according to an embodiment of the present invention;

FIG. 9 is a schematic cross-sectional plan view of the thin film deposition assembly of FIG. 7, according to an embodiment of the present invention;

FIG. 10 is a perspective view of a thin film deposition assembly according to another embodiment of the present invention;

FIG. 11 is a perspective view of a thin film deposition assembly according to another embodiment of the present invention;

FIG. 12 is a perspective view of a thin film deposition assembly according to another embodiment of the present invention;

FIG. 13 is a schematic cross-sectional side view of the thin film deposition assembly of FIG. 12, according to an embodiment of the present invention;

FIG. 14 is a schematic cross-sectional plan view of the thin film deposition assembly of FIG. 12, according to an embodiment of the present invention;

FIG. 15 is a perspective view of a thin film deposition assembly according to another embodiment of the present invention; and

FIG. 16 is a cross-sectional view of an organic light-emitting display device manufactured by using a thin film deposition assembly, according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain aspects of the present invention by referring to the figures

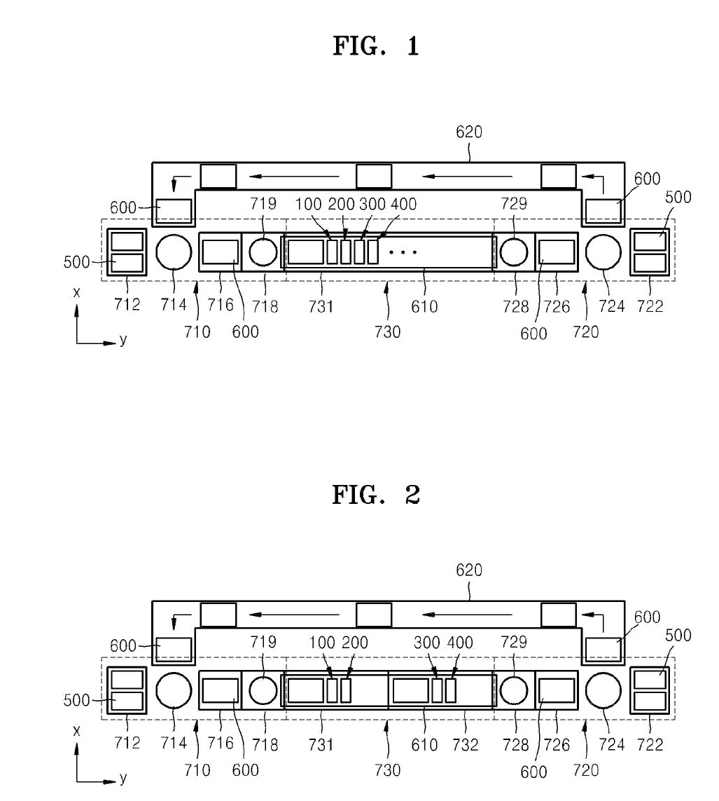

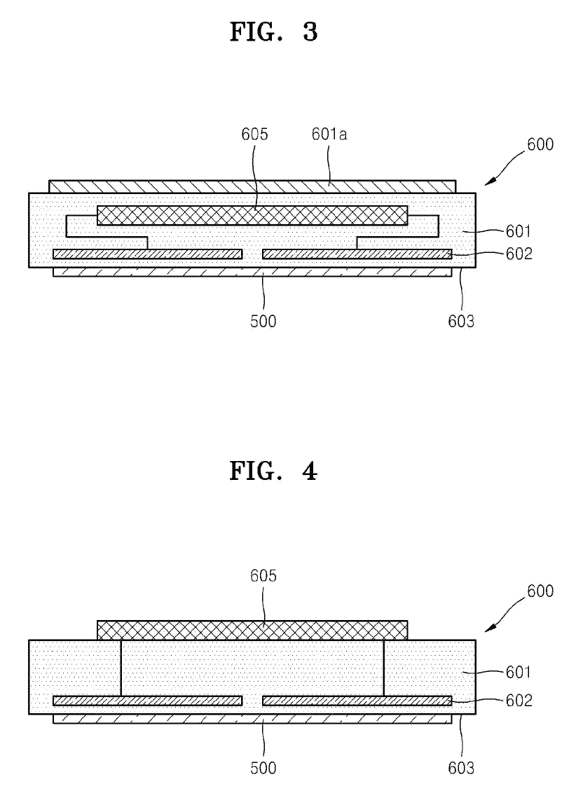

FIG. 1 is a schematic perspective view of a thin film deposition apparatus according to an embodiment of the present invention. FIG. 2 illustrates a modified example of the thin film deposition apparatus of FIG. 1. FIG. 3 is a view of an example of an electrostatic chuck 600.

Referring to FIG. 1, the thin film deposition apparatus according to the current embodiment includes a loading unit 710, a deposition unit 730, an unloading unit 720, a first circulating unit 610 and a second circulating unit 620.

The loading unit 710 may include a first rack 712, a transport robot 714, a transport chamber 716, and a first inversion chamber 718.

A plurality of substrates 500 onto which a deposition material has not yet been applied are stacked up on the first rack 712. The transport robot 714 picks up one of the substrates 500 from the first rack 712, disposes it on the electrostatic chuck 600 transferred by the second circulating unit 620, and moves the electrostatic chuck 600 on which the substrate 500 is disposed into the transport chamber 716. Although it is not shown in FIGS. 1 and 2, the transport robot 714 may be disposed in a chamber that has an appropriate degree of vacuum maintained therein.

The first inversion chamber 718 is disposed adjacent to the transport chamber 716. The first inversion chamber 718 includes a first inversion robot 719 that inverts the electrostatic chuck 600 and then loads it into the first circulating unit 610 of the deposition unit 730.

The electrostatic chuck 600 according to the current embodiment of the present invention includes an electrode 602 to which an electric power is applied in a main body 601 formed of a dielectric material, as shown in FIG. 3. The electrode 602 is separated by a predetermined distance from a supporting surface 603 that faces the substrate 500, and an electrostatic force is applied to the supporting surface 603 from the electrode 602 to adhere and fix the substrate 500 thereon.

The main body 601 includes a predetermined space in which a battery 605 is installed. The battery 605 is electrically connected to the electrode 602 to apply electric power to the electrode 602.

A cover 601a is installed on an opposite surface of the supporting surface 603 so that the battery 605 may be inserted into or removed from the main body 601.

In the electrostatic chuck 600, an additional power line is not necessary since the power is applied to the electrode 602 from the battery 605 that is installed in the main body 601. Therefore, it is easy to move the electrostatic chuck 600 that supports the substrate 500 in the chamber or between chambers, and it is easy to provide a thin film deposition apparatus.

As shown in FIG. 4, the battery 605 may be installed on an outer portion of the main body 601. In this case, since the battery 605 is exposed to a deposition environment in the chamber, an additional case for covering the battery 605 may be formed.

Referring to FIG. 1, the transport robot 714 places one of the substrates 500 on the surface of the electrostatic chuck 600, and the electrostatic chuck 600 on which the substrate 500 is disposed is loaded into the transport chamber 716. The first inversion robot 719 inverts the electrostatic chuck 600 so that the substrate 500 is turned upside down in the deposition unit 730. In more detail, the electrostatic chuck 600 is inverted so that the substrate 500 will face the thin film deposition assemblies 100, 200, 300, and 400 when the electrostatic chuck 600 and substrate pass through the deposition unit 730, to be described later. The transport chamber 716 and the first inversion chamber 718 may have an appropriate degree of vacuum maintained therein.

The unloading unit 720 is constituted to operate in an opposite manner to the loading unit 710 described above. Specifically, a second inversion robot 729 in a second inversion chamber 728 inverts the electrostatic chuck 600, which has passed through the deposition unit 730 while the substrate 500 is disposed on the electrostatic chuck 600, and then moves the electrostatic chuck 600 on which the substrate 500 is disposed into an ejection chamber 726. Then, an ejection robot 724 removes the electrostatic chuck 600 on which the substrate 500 is disposed from the ejection chamber 726, separates the substrate 500 from the electrostatic chuck 600, and then loads the substrate 500 into the second rack 722. The electrostatic chuck 600 separated from the substrate 500 is returned back into the loading unit 710 via the second circulating unit 620. The second inversion chamber 728 and the ejection chamber 726 may have an appropriate degree of vacuum maintained therein. In addition, although it is not shown in the drawings, the ejection robot 724 may be disposed in a chamber that has an appropriate degree of vacuum maintained therein.

However, the present invention is not limited to the above description. For example, when disposing the substrate 500 on the electrostatic chuck 600, the substrate 500 may be fixed onto a bottom surface of the electrostatic chuck 600 and then moved into the deposition unit 730. (In FIGS. 1 and 2, terms such as “top surface” and “bottom surface” are with reference to a “top surface” being a surface facing the viewer in FIGS. 1 and 2 and “a bottom surface” as being a surface facing away from the viewer.) In this case, for example, the first inversion chamber 718 and the first inversion robot 719, and the second inversion chamber 728 and the second inversion robot 729 are not required.

The deposition unit 730 includes at least one deposition chamber. As illustrated in FIG. 1, the deposition unit 730 may include a first chamber 731. As a non-limiting example, first to fourth thin film deposition assemblies 100, 200, 300, and 400 may be disposed in the first chamber 731. Although FIG. 1 illustrates that a total of four thin film deposition assemblies, i.e., the first to fourth thin film deposition assemblies 100 to 400, are installed in the first chamber 731, the total number of thin film deposition assemblies that may be installed in the first chamber 731 may vary according to a deposition material and deposition conditions. The first chamber 731 is maintained in a vacuum state during a deposition process.

In the thin film deposition apparatus illustrated in FIG. 2, a deposition unit 730 may include a first chamber 731 and a second chamber 732 that are connected to each other. In this case, first and second thin film deposition assemblies 100 and 200 may be disposed in the first chamber 731, and third and fourth thin film deposition assemblies 300 and 400 may be disposed in the second chamber 732. In this regard, the number of chambers may be increased.

In the embodiment illustrated in FIG. 1, the electrostatic chuck 600 on which the substrate 500 is disposed may be moved at least to the deposition unit 730 or may be moved sequentially to the loading unit 710, the deposition unit 730, and the unloading unit 720, by the first circulating unit 610. The electrostatic chuck 600 that is separated from the substrate 500 in the unloading unit 720 is moved back to the loading unit 710 by the second circulating unit 620.

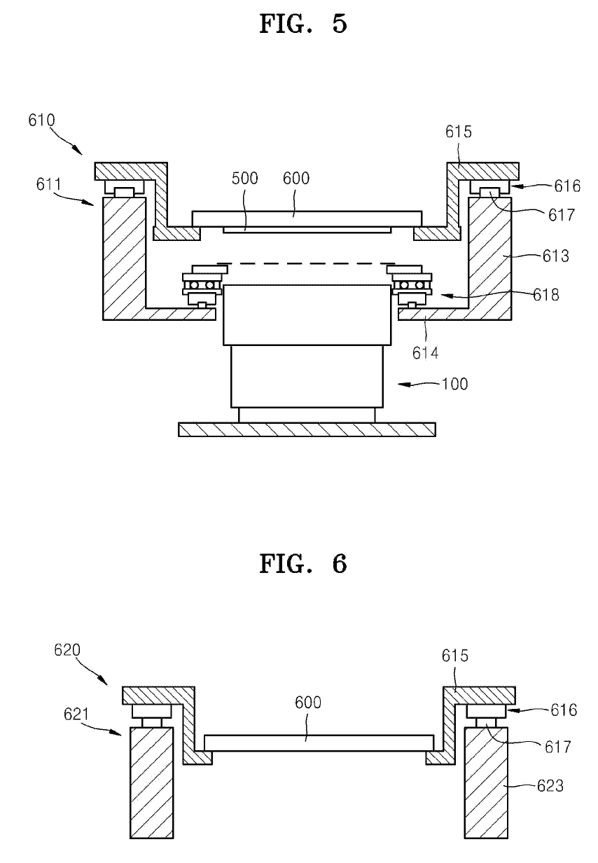

FIG. 5 is a cross-sectional view of the first circulating unit 610, according to an embodiment of the present invention.

The first circulating unit 610 includes a first carrier 611 that moves the electrostatic chuck 600 on which the substrate 500 is disposed.

The first carrier 611 includes a first support 613, a second support 614, a movement bar 615, and a first driving unit 616.

The first support 613 and the second support 614 are installed to extend through a chamber in the deposition unit 730, for example, the first chamber 731 in the embodiment shown in FIG. 1, and the first chamber 731 and the second chamber 732 in the embodiment shown in FIG. 2.

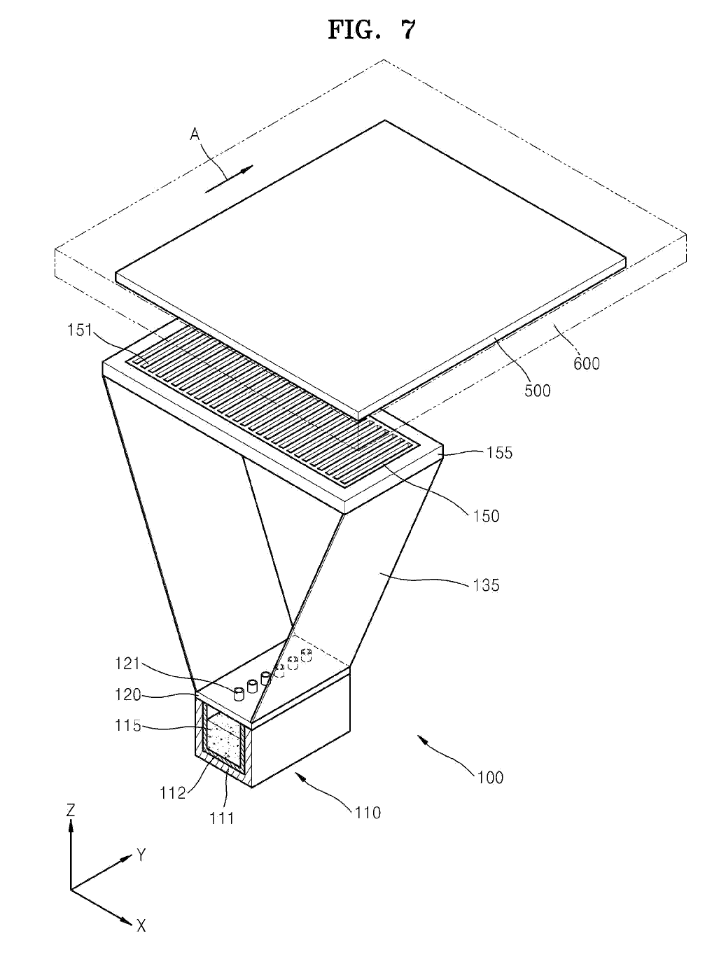

The first support 613 is disposed vertically in the first chamber 731, and the second support 614 is horizontally disposed below the first support 613 in the first chamber 731. (In FIGS. 5 and 6, the term “vertically” refers to a direction between a thin film deposition assembly, such as thin film deposition assembly 100, and the substrate 500 and “horizontally” refers to a direction perpendicular to such vertical direction and perpendicular to a direction of motion of the substrate through the deposition unit 730. In more detail, the vertical direction and the horizontal direction in FIGS. 5 and 6 correspond to the Z direction and the X direction, respectively, as shown in FIGS. 7 to 15. As illustrated in FIG. 5, the first support 613 and the second support 614 may be disposed perpendicular to each other forming a bent structure. However, the present invention is not limited to this structure, and the first support 613 and the second support 614 may have any structure, provided that the first support 613 is disposed above the second support 614.

The movement bar 615 is movable along the first support 613. One end of the movement bar 615 is supported by the first support 613, and the other end of the movement bar 615 supports an edge of the electrostatic chuck 600. The electrostatic chuck 600 is supported by the movement bar 615 and the electrostatic chuck 600 and the movement bar 615 together are movable along the first support 613. A portion of the movement bar 615 supporting the electrostatic chuck 600 is bent toward the thin film deposition assembly 100, and thus can reduce the distance between the substrate 500 and the thin film deposition assembly 100.

The first driving unit 616 is disposed between the movement bar 615 and the first support 613 and moves the movement bar 615 along the first support 613. The first driving unit 616 may include a roller 617 rolling along the first support 613. In this regard, the first support 613 may be in the form of a rail extending in a direction perpendicular to the X and Z directions as described above, or in other words, in a direction perpendicular to the plane of the cross-sectional view of FIG. 5. The first driving unit 616 may generate a driving force by itself or may transfer a driving force generated by a separate driving source to the movement bar 615. The first driving unit 616 may include any driving element, in addition to the roller 617, provided that it can move the movement bar 615.

FIG. 6 is a cross-sectional view of the second circulating unit 620, according to an embodiment of the present invention.

The second circulating unit 620 includes a second carrier 621 that moves the electrostatic chuck 600 from which the substrate 500 is separated.

The second carrier 621 includes a first support 623, the movement bar 615, and the first driving unit 616.

The third support 623 extends in a similar manner to the first support 613 of the first carrier 611. The third support 623 supports the movement bar 615 having the first driving unit 616, and the electrostatic chuck 600 that has been separated from the substrate 500 is mounted on the movement bar 615. Structures of the movement bar 615 and the first driving unit 616 have already been described above, and thus descriptions thereof will not be provided here.

The system for moving the electrostatic chuck 600 is not limited to the above embodiment, and the electrostatic chuck 600 may be simply moved along a rail by using an additional roller or a chain system.

Hereinafter, an embodiment of the thin film deposition assembly 100 disposed in the first chamber 731 will be described.

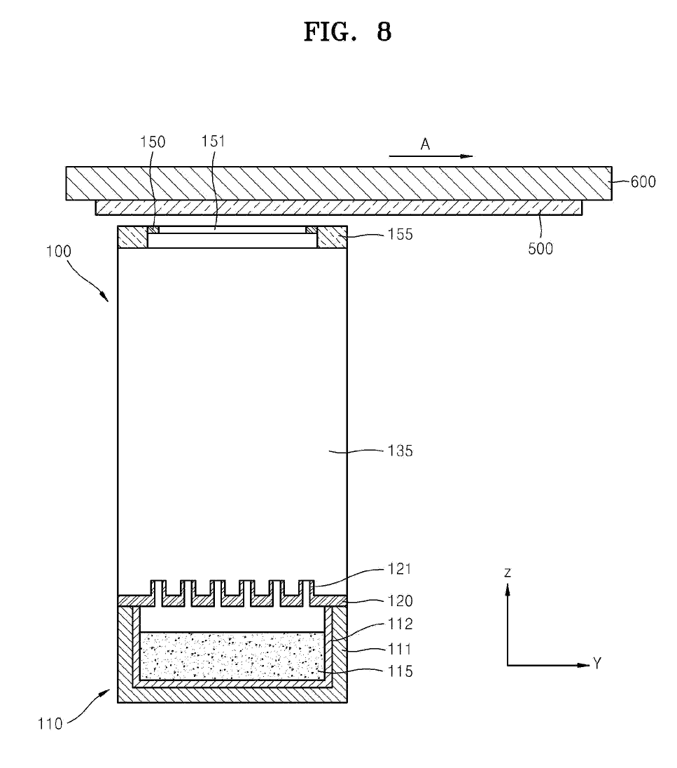

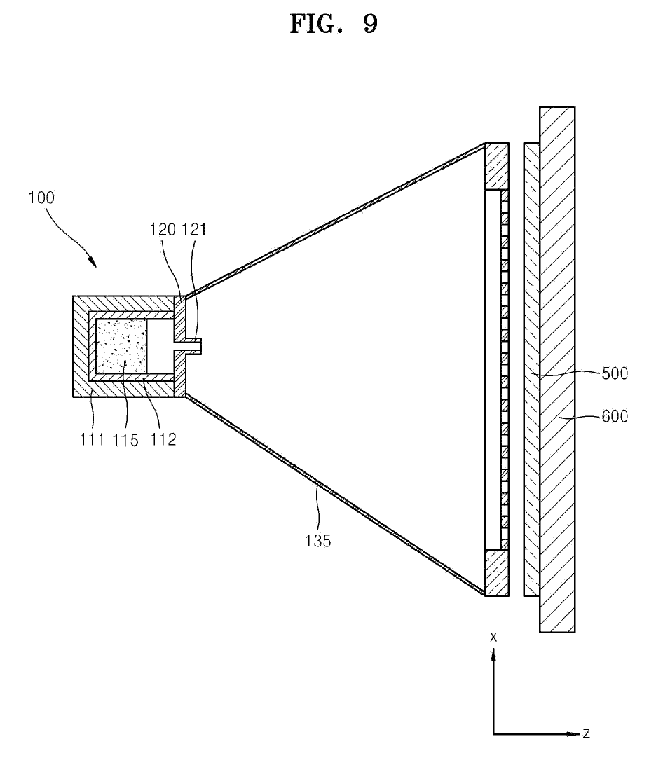

FIG. 7 is a schematic perspective view of a thin film deposition assembly 100 according to an embodiment of the present invention, FIG. 8 is a schematic side view of the thin film deposition apparatus 100, and FIG. 9 is a schematic plan view of the thin film deposition apparatus 100.

Referring to FIGS. 7 through 9, the thin film deposition assembly 100 according to the current embodiment of the present invention includes a deposition source 110, a deposition source nozzle unit 120, and a patterning slit sheet 150.

In particular, in order to deposit a deposition material 115 that is emitted from the deposition source 110 and is discharged through the deposition source nozzle unit 120 and the patterning slit sheet 150, onto a substrate 500 in a desired pattern, it is desirable to maintain the first chamber 731 in a high-vacuum state as in a deposition method using a fine metal mask (FMM). In addition, the temperature of the patterning slit sheet 150 should be sufficiently lower than the temperature of the deposition source 110. In this regard, the temperature of the patterning slit sheet 150 may be about 100° C. or less. The temperature of the patterning slit sheet 150 should be sufficiently low so as to reduce thermal expansion of the patterning slit sheet 150.

The substrate 500, which constitutes a deposition target on which a deposition material 115 is to be deposited, is disposed in the first chamber 731. The substrate 500 may be a substrate for flat panel displays. A large substrate, such as a mother glass, for manufacturing a plurality of flat panel displays, may be used as the substrate 400. Other substrates may also be employed. The substrate 500 may be affixed to the electrostatic chuck 600 as described above.

In the current embodiment of the present invention, deposition may be performed while the substrate 500 or the thin film deposition assembly 100 is moved relative to the other. Herein, where it is stated that the substrate or thin film deposition assembly are moved relative to the other, it is to be understood that such statement encompasses an embodiment in which only the substrate is moved and the thin film deposition assembly remains stationary, an embodiment in which only the thin film deposition assembly is moved and the substrate remains stationary and an embodiment in which both the thin film deposition assembly and the substrate are moved.

In particular, in the conventional FMM deposition method, the size of the FMM has to be equal to the size of a substrate. Thus, the size of the FMM has to be increased when larger substrates are used. However, it is difficult to manufacture a large FMM and to extend an FMM to be accurately aligned with a pattern.

In order to overcome this problem, in the thin film deposition assembly 100 according to the current embodiment of the present invention, deposition may be performed while the thin film deposition assembly 100 or the substrate 500 is moved relative to the other. In more detail, deposition may be continuously performed while the substrate 500, which is disposed to face the thin film deposition assembly 100, is moved in a Y-axis direction. In other words, deposition is performed in a scanning manner while the substrate 500 is moved in a direction of arrow A in FIG. 7.

In the thin film deposition assembly 100 according to the current embodiment of the present invention, the patterning slit sheet 150 may be significantly smaller than an FMM used in a conventional deposition method. In more detail, in the thin film deposition assembly 100 according to the current embodiment of the present invention, deposition is continuously performed, i.e., in a scanning manner, while the substrate 500 is moved in the Y-axis direction. Thus, lengths of the patterning slit sheet 950 in the X-axis and Y-axis directions may be significantly less than the lengths of the substrate 500 in the X-axis and Y-axis directions. As described above, since the patterning slit sheet 150 may be formed to be significantly smaller than an FMM used in a conventional deposition method, it is relatively easy to manufacture the patterning slit sheet 150 used in aspects of the present invention. In other words, using the patterning slit sheet 150, which is smaller than an FMM used in a conventional deposition method, is more convenient in all processes, including etching and other subsequent processes, such as precise extension, welding, moving, and cleaning processes, compared using a larger FMM according to the conventional deposition method. Accordingly, the use of the patterning slit sheet 150 is more advantageous than the use of a conventional FMM for manufacturing a relatively large display device.

The deposition source 110, which contains and heats the deposition material 115, is disposed in an opposite side of the thin film deposition assembly 100 from a side in which the substrate 500 is disposed. When the deposition material 115 contained in the deposition source 110 is vaporized, the deposition material 115 is deposited on the substrate 500.

In particular, the deposition source 110 includes a crucible 112 that is filled with the deposition material 115, and a heater (not shown) that heats the crucible 112 to vaporize the deposition material 115 that is contained in the crucible 112, such that the deposition material 115 is directed towards the deposition source nozzle unit 120. The cooling block 111 prevents the radiation of heat from the crucible 112 to the outside, i.e., into the first chamber 731. The heater may be incorporated in the cooling block 111.

The deposition source nozzle unit 120 is disposed at a side of the deposition source 110, and in particular, at the side of the deposition source 110 facing the substrate 500. The deposition source nozzle unit 120 includes a plurality of deposition source nozzles 121 arranged at equal intervals in the Y-axis direction, i.e., a scanning direction of the substrate 500. The deposition material 115 that is vaporized in the deposition source 110, passes through the deposition source nozzle unit 120 towards the substrate 500. As described above, when the deposition source nozzle unit 120 includes the plurality of deposition source nozzles 121 arranged in the Y-axis direction, that is, the scanning direction of the substrate 500, the size of a pattern formed of the deposition material discharged through the patterning slits 151 of the patterning slit sheet 150 is affected by the size of each of the deposition source nozzles 121 (since there is only one line of deposition nozzles in the X-axis direction), and thus no shadow zone may be formed on the substrate 500. In addition, since the plurality of deposition source nozzles 121 are arranged in the scanning direction of the substrate 500, even if there is a difference in flux between the deposition source nozzles 121, the difference may be compensated for and deposition uniformity may be maintained constant.

The patterning slit sheet 150 and a frame 155 in which the patterning slit sheet 150 is bound are disposed between the deposition source 110 and the substrate 500. The frame 155 may be formed in a lattice shape, similar to a window frame. The patterning slit sheet 150 is bound inside the frame 155. The patterning slit sheet 150 includes a plurality of patterning slits 151 arranged in the X-axis direction. The deposition material 115 that is vaporized in the deposition source 110, passes through the deposition source nozzle unit 120 and the patterning slit sheet 150 towards the substrate 500. The patterning slit sheet 150 may be manufactured by etching, which is the same method as used in a conventional method of manufacturing an FMM, and in particular, a striped FMM. In this regard, the total number of patterning slits 151 may be greater than the total number of deposition source nozzles 121.

In addition, the deposition source 110 and the deposition source nozzle unit 120 coupled to the deposition source 110 may be disposed to be spaced apart from the patterning slit sheet 150 by a predetermined distance. Alternatively, the deposition source 110 and the deposition source nozzle unit 120 coupled to the deposition source 110 may be connected to the patterning slit sheet 150 by a first connection member 135. That is, the deposition source 110, the deposition source nozzle unit 120, and the patterning slit sheet 150 may be integrally formed as one body by being connected to each other via the first connection member 135. The first connection member 135 guides the deposition material 121, which is discharged through the deposition source nozzles 921, to move straight, not to deviate in the X-axis direction. In FIG. 7, the first connection members 135 are formed on left and right sides of the deposition source 110, the deposition source nozzle unit 120, and the patterning slit sheet 150 to guide the deposition material 115 not to deviate in the X-axis direction; however, aspects of the present invention are not limited thereto. That is, the first connection member 135 may be formed as a sealed box to guide flow of the deposition material 915 both in the X-axis and Y-axis directions.

As described above, the thin film deposition assembly 100 according to the current embodiment of the present invention performs deposition while being moved relative to the substrate 500. In order to move the thin film deposition assembly 100 relative to the substrate 500, the patterning slit sheet 150 is spaced apart from the substrate 500 by a predetermined distance.

In particular, in a conventional deposition method using an FMM, deposition is performed with the FMM in close contact with a substrate in order to prevent formation of a shadow zone on the substrate. However, when the FMM is used in close contact with the substrate, the contact may cause defects. In addition, in the conventional deposition method, the size of the mask has to be the same as the size of the substrate since the mask cannot be moved relative to the substrate. Thus, the size of the mask has to be increased as display devices become larger. However, it is not easy to manufacture such a large mask.

In order to overcome this problem, in the thin film deposition assembly 100 according to the current embodiment of the present invention, the patterning slit sheet 150 is disposed to be spaced apart from the substrate 500 by a predetermined distance.

As described above, according to aspects of the present invention, a mask is formed to be smaller than a substrate, and deposition is performed while the mask is moved relative to the substrate. Thus, the mask can be easily manufactured. In addition, defects caused due to the contact between a substrate and an FMM, which occur in the conventional deposition method, may be prevented. Furthermore, since it is unnecessary to dispose the FMM in close contact with the substrate during a deposition process, the manufacturing time may be reduced.

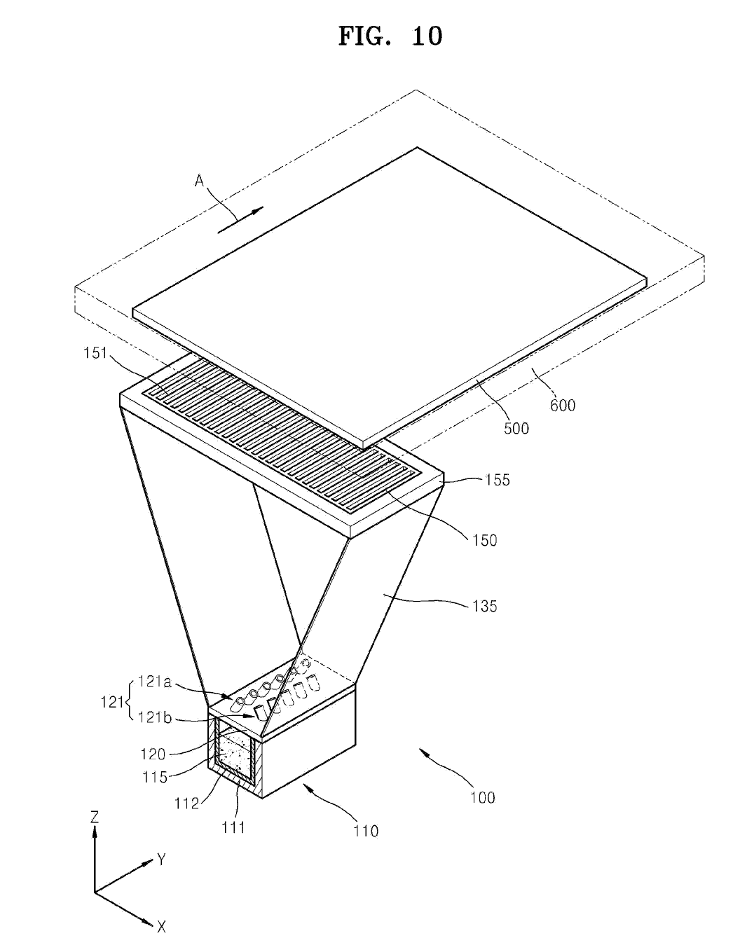

FIG. 10 is a perspective view of a thin film deposition assembly according to another embodiment of the present invention. Referring to FIG. 10, the thin film deposition assembly 100 according to the current embodiment of the present invention includes a deposition source 110, a deposition source nozzle unit 120, and a patterning slit sheet 150. In particular, the deposition source 110 includes a crucible 112 that is filled with the deposition material 115, and a cooling block 111 including a heater that heats the crucible 112 to vaporize the deposition material 115 that is contained in the crucible 112, so as to move the vaporized deposition material 115 to the deposition source nozzle unit 120. The deposition source nozzle unit 120, which has a planar shape, is disposed at a side of the deposition source 110. The deposition source nozzle unit 120 includes a plurality of deposition source nozzles 121 arranged in the Y-axis direction. The patterning slit sheet 150 and a frame 155 are further disposed between the deposition source 110 and the substrate 500. The patterning slit sheet 150 includes a plurality of patterning slits 151 arranged in the X-axis direction. In addition, the deposition source 110 and the deposition source nozzle unit 120 may be connected to the patterning slit sheet 150 by the second connection member 133.

In the current embodiment, a plurality of deposition source nozzles 121 formed on the deposition source nozzle unit 120 are tilted at a predetermined angle, unlike the thin film deposition assembly described with reference to FIGS. 7 to 9. In particular, the deposition source nozzles 121 may include deposition source nozzles 121a and 121b arranged in respective rows. The deposition source nozzles 121a and 121b may be arranged in respective rows to alternate in a zigzag pattern. The deposition source nozzles 121a and 121b may be tilted at a predetermined angle on an XZ plane.

In the current embodiment of the present invention, the deposition source nozzles 121a and 121b are arranged to tilt at a predetermined angle toward each other. The deposition source nozzles 121a in a first row and the deposition source nozzles 121b in a second row may tilt at the predetermined angle to face each other. That is, the deposition source nozzles 121a of the first row in a left part of the deposition source nozzle unit 120 may tilt to face a right side portion of the patterning slit sheet 150, and the deposition source nozzles 121b of the second row in a right part of the deposition source nozzle unit 120 may tilt to face a left side portion of the patterning slit sheet 150.

Due to the structure of the thin film deposition assembly 100 according to the current embodiment, the deposition of the deposition material 115 may be adjusted to lessen a thickness variation between the center and the end portions of the substrate 500 and improve thickness uniformity of the deposition film. Moreover, utilization efficiency of the deposition material 115 may also be improved.

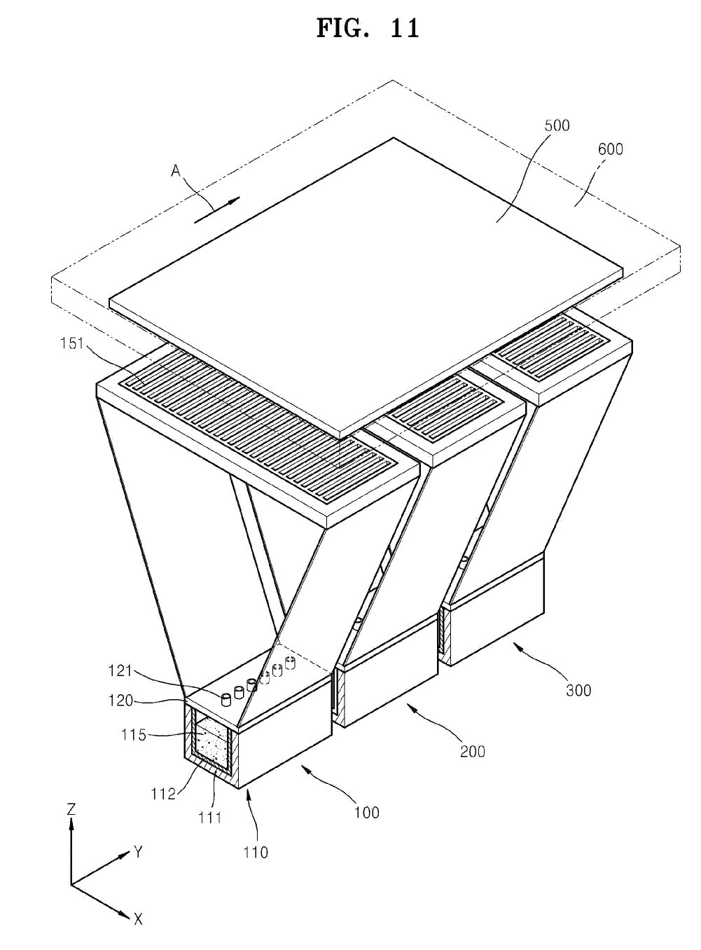

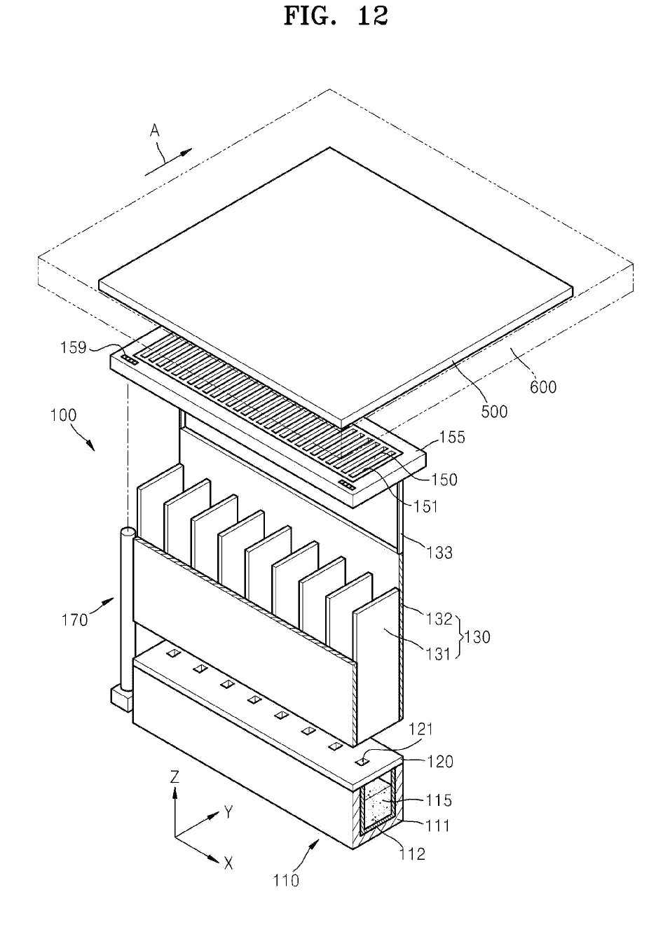

FIG. 11 is a perspective view of a thin film deposition apparatus according to another embodiment of the present invention. Referring to FIG. 11, the thin film deposition apparatus according to the current embodiment of the present invention includes a plurality of thin film deposition assemblies 100, 200, 300, each of which has the structure of the thin film deposition assembly 100 illustrated in FIGS. 7 through 9. In other words, the thin film deposition apparatus according to the current embodiment of the present invention may include a multi-deposition source that simultaneously discharges deposition materials for forming an R emission layer, a G emission layer, and a B emission layer.

In particular, the thin film deposition apparatus according to the current embodiment of the present invention includes a first thin film deposition assembly 100, a second thin film deposition assembly 200, and a third thin film deposition assembly 300. Each of the first thin film deposition assembly 100, the second thin film deposition assembly 200, and the third thin film deposition assembly 300 has the same structure as the thin film deposition assembly described with reference to FIGS. 7 through 9, and thus a detailed description thereof will not be repeated here.

The deposition sources 110 of the first thin film deposition assembly 100, the second thin film deposition assembly 200 and the third thin film deposition assembly 300 may contain different deposition materials, respectively. The first thin film deposition assembly 100 may contain a deposition material for forming the R emission layer, the second thin film deposition assembly 200 may contain a deposition material for forming the G emission layer, and the third thin film deposition assembly 300 may contain a deposition material for forming the B emission layer.

In other words, in a conventional method of manufacturing an organic light-emitting display device, a separate chamber and mask are used to form each color emission layer. However, when the thin film deposition apparatus according to the current embodiment of the present invention is used, the R emission layer, the G emission layer and the B emission layer may be formed at the same time with a single multi-deposition source. Thus, the time it takes to manufacture the organic light-emitting display device is sharply reduced. In addition, the organic light-emitting display device may be manufactured with a reduced number of chambers, so that equipment costs are also markedly reduced.

Although not illustrated, a patterning slit sheet of the first thin film deposition assembly 100, a patterning slit sheet of the second thin film deposition assembly 200, a patterning slit sheet of the third thin film deposition assembly 300 may be arranged to be offset by a constant distance with respect to each other, in order for deposition regions corresponding to the patterning slit sheets 150, 250 and 350 not to overlap on the substrate 400. In other words, when the first thin film deposition assembly 100, the second thin film deposition assembly 200, and the third thin film deposition assembly 200 are used to deposit the R emission layer, the G emission layer and the B emission layer, respectively, patterning slits 151 of the first thin film deposition assembly 100, patterning slits 251 of the second thin film deposition assembly 200, and patterning slits 351 of the second thin film deposition assembly 300 are arranged not to be aligned with respect to each other, in order to form the R emission layer, the G emission layer and the B emission layer in different regions of the substrate 500.

In addition, the deposition materials for forming the R emission layer, the G emission layer, and the B emission layer may have different deposition temperatures. Therefore, the temperatures of the deposition sources of the respective first, second, and third thin film deposition assemblies 100, 200, and 300 may be set to be different.

Although the thin film deposition apparatus according to the current embodiment of the present invention includes three thin film deposition assemblies, the present invention is not limited thereto. In other words, a thin film deposition apparatus according to another embodiment of the present invention may include a plurality of thin film deposition assemblies, each of which contains a different deposition material. For example, a thin film deposition apparatus according to another embodiment of the present invention may include five thin film deposition assemblies respectively containing materials for an R emission layer, a G emission layer, a B emission layer, an auxiliary layer (R′) of the R emission layer, and an auxiliary layer (G′) of the G emission layer. Moreover, thin film deposition assemblies 100, 200, 300 may be located in a single deposition chamber 731 as shown in FIG. 1 or in separate deposition chambers 731 and 732 housed in a single deposition unit 730 as shown in FIG. 2 through which a circulating unit 610 conveys an electrostatic chuck 600 to which a substrate 500 is affixed.

As described above, a plurality of thin films may be formed at the same time with a plurality of thin film deposition assemblies, and thus manufacturing yield and deposition efficiency are improved. In addition, the overall manufacturing process is simplified, and the manufacturing costs are reduced.

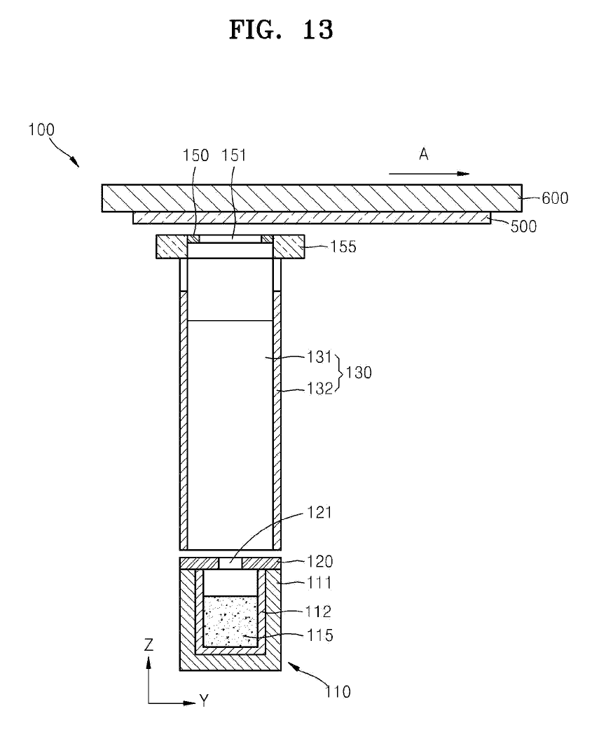

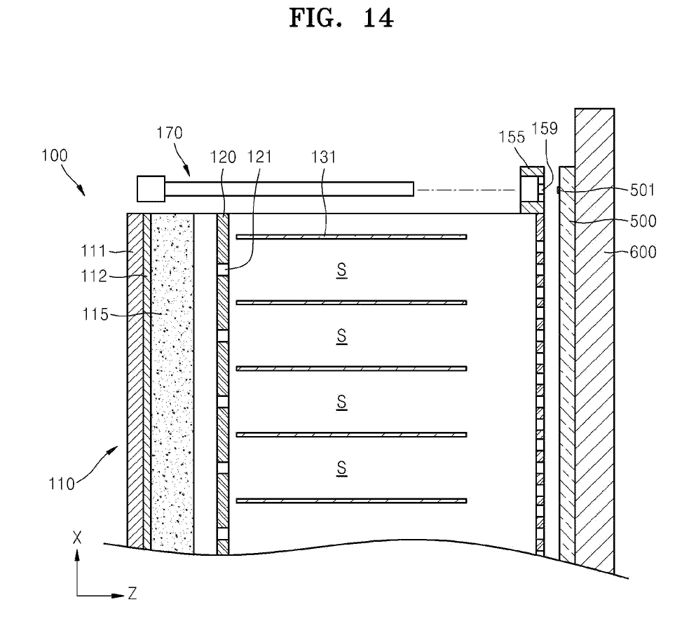

FIG. 12 is a schematic perspective view of a thin film deposition assembly 100 according to an embodiment of the present invention, FIG. 13 is a schematic cross-sectional side view of the thin film deposition assembly 100 of FIG. 12, and FIG. 14 is a schematic cross-sectional plan view of the thin film deposition assembly 100 of FIG. 12.

Referring to FIGS. 12 through 14, the thin film deposition assembly 100 according to the current embodiment of the present invention includes a deposition source 110, a deposition source nozzle unit 120, a barrier plate assembly 130, and patterning slits 151.

Although a chamber is not illustrated in FIGS. 12 through 14 for convenience of explanation, all the components of the thin film deposition assembly 100 may be disposed within a chamber that is maintained at an appropriate degree of vacuum. The chamber is maintained at an appropriate vacuum in order to allow a deposition material to move in a substantially straight line through the thin film deposition apparatus 100.

In the chamber in which the thin film deposition assembly 100 is disposed, the substrate 500, which constitutes a deposition target on which the deposition material 115 is to be deposited, is transferred by the electrostatic chuck 600. The substrate 500 may be a substrate for flat panel displays. A large substrate, such as a mother glass, for manufacturing a plurality of flat panel displays, may be used as the substrate 500. Other substrates may also be employed.

In an embodiment, the substrate 500 or the thin film deposition assembly 100 may be moved relative to the other. For example, as illustrated in FIG. 12, the substrate 500 may be moved in a direction of an arrow A, relative to the thin film deposition assembly 100.

In the thin film deposition assembly 100 according to the current embodiment of the present invention, the patterning slit sheet 150 may be significantly smaller than an FMM used in a conventional deposition method. In other words, in the thin film deposition assembly 100, deposition is continuously performed, i.e., in a scanning manner, while the substrate 500 is moved in the Y-axis direction. Thus, a length of the patterning slit sheet 150 in the Y-axis direction may be significantly less than a length of the substrate 500 in the Y-axis direction. A width of the patterning slit sheet 150 in the X-axis direction and a width of the substrate 500 in the X-axis direction may be substantially equal to each other. However, even when the width of the patterning slit sheet 150 in the X-axis direction is less than the width of the substrate 500 in the X-axis direction, deposition may be performed on the entire substrate 500 in a scanning manner while the substrate 500 or the thin film deposition assembly 100 is moved relative each other.

As described above, since the patterning slit sheet 150 may be formed to be significantly smaller than an FMM used in a conventional deposition method, it is relatively easy to manufacture the patterning slit sheet 150 used in aspects of the present invention. In other words, using the patterning slit sheet 150, which is smaller than an FMM used in a conventional deposition method, is more convenient in all processes, including etching and other subsequent processes, such as precise extension, welding, moving, and cleaning processes, compared to the conventional deposition method using the larger FMM. Accordingly, the use of the patterning slit sheet 150 is more advantageous than the use of a conventional FMM for manufacturing a relatively large display device.

The deposition source 110 that contains and heats the deposition material 115 is disposed in an opposite side of the first chamber from the side in which the substrate 500 is disposed.

The deposition source 110 includes a crucible 112 that is filled with the deposition material 115, and a cooling block 111 surrounding the crucible 112. The cooling block 111 prevents radiation of heat from the crucible 112 outside, i.e., into the first chamber. The cooling block 111 may include a heater (not shown) that heats the crucible 111.

The deposition source nozzle unit 120 is disposed at a side of the deposition source 110, and in particular, at the side of the deposition source 110 facing the substrate 500. The deposition source nozzle unit 120 includes a plurality of deposition source nozzles 121 arranged at equal intervals in the X-axis direction. The deposition material 115 that is vaporized in the deposition source 110 passes through the deposition source nozzles 121 of the deposition source nozzle unit 120 towards the substrate 500, which constitutes a target on which the deposition material 115 is to be deposited.

The barrier plate assembly 130 is disposed at a side of the deposition source nozzle unit 120 between the deposition source nozzle unit 120 and the patterning slit sheet 150. The barrier plate assembly 130 includes a plurality of barrier plates 131, and a barrier plate frame 132 that covers sides of the barrier plates 131. The plurality of barrier plates 131 may be arranged parallel to each other at equal intervals in the X-axis direction. In addition, each of the barrier plates 131 may be arranged parallel to a Y-Z plane in FIG. 12, and may have a rectangular shape. The plurality of barrier plates 131 arranged as described above partition the space between the deposition source nozzle unit 120 and the patterning slit sheet 150 into a plurality of sub-deposition spaces S (see FIG. 14). In the thin film deposition assembly 100 according to the current embodiment of the present invention, as illustrated in FIG. 14, the deposition space is divided by the barrier plates 131 into the sub-deposition spaces S that respectively correspond to the deposition source nozzles 121 through which the deposition material 115 is discharged.

The barrier plates 131 may be respectively disposed between adjacent deposition source nozzles 121. In other words, each of the deposition source nozzles 121 may be disposed between two adjacent barrier plates 131. The deposition source nozzles 121 may be respectively located at the midpoint between two adjacent barrier plates 131. However, the present invention is not limited to this structure. For example, a plurality of deposition source nozzles 121 may be disposed between two adjacent barrier plates 131. In this case, the deposition source nozzles 121 may be also respectively located at the midpoint between two adjacent barrier plates 131.

As described above, since the barrier plates 131 partition the space between the deposition source nozzle unit 120 and the patterning slit sheet 150 into the plurality of sub-deposition spaces S, the deposition material 115 discharged through each of the deposition source nozzles 121 is not mixed with the deposition material 115 discharged through the other deposition source nozzles slits 121, and passes through the patterning slits 151 so as to be deposited on the substrate 500. In other words, the barrier plates 131 guide the deposition material 115, which is discharged through the deposition source nozzles slits 121, to move straight, and not to deviate in the X-axis direction.

As described above, the deposition material 115 is forced to move straight by installing the barrier plates 131, so that a smaller shadow zone may be formed on the substrate 500 compared to a case where no barrier plates are installed. Thus, the thin film deposition assembly 100 and the substrate 500 can be spaced apart from each other by a predetermined distance. This will be described later in detail.

The barrier plate frame 132, which forms sides of the barrier plates 131, maintains the positions of the barrier plates 131, and guides the deposition material 115, which is discharged through the deposition source nozzles 121, and prevents deviation of the deposition material in the Y-axis direction.

The deposition source nozzle unit 120 and the barrier plate assembly 130 may be separated from each other by a predetermined distance. This separation may prevent the heat radiated from the deposition source unit 110 from being conducted to the barrier plate assembly 130. However, aspects of the present invention are not limited to this feature. For example, an appropriate heat insulator (not shown) may be further disposed between the deposition source nozzle unit 120 and the barrier plate assembly 130. In this case, the deposition source nozzle unit 120 and the barrier plate assembly 130 may be bound together with the heat insulator therebetween.

In addition, the barrier plate assembly 130 may be constructed to be detachable from the thin film deposition assembly 100. In the thin film deposition assembly 100 of the thin film deposition apparatus according to the current embodiment of the present invention, the deposition space is enclosed by using the barrier plate assembly 130, so that the deposition material 115 that is not deposited on the substrate 500 is mostly deposited within the barrier plate assembly 130. Thus, since the barrier plate assembly 130 is constructed to be detachable from the thin film deposition assembly 100, when a large amount of the deposition material 115 is present on the barrier plate assembly 130 after a long deposition process, the barrier plate assembly 130 may be detached from the thin film deposition assembly 100 and then placed in a separate deposition material recycling apparatus in order to recover the deposition material 115. Due to the structure of the thin film deposition assembly 100 according to the present embodiment, a reuse rate of the deposition material 115 is increased, so that the deposition efficiency is improved, and thus the manufacturing costs are reduced.

The patterning slit sheet 150 and a frame 155 in which the patterning slit sheet 150 is bound are disposed between the deposition source 110 and the substrate 500. The frame 155 may be formed in a lattice shape, similar to a window frame. The patterning slit sheet 150 is bound inside the frame 155. The patterning slit sheet 150 includes a plurality of patterning slits 151 arranged in the X-axis direction. The patterning slits 151 extend as openings in the Y-axis direction. The deposition material 115 that has been vaporized in the deposition source 110 and passed through the deposition source nozzle 121 passes through the patterning slits 151 towards the substrate 500.

The patterning slit sheet 150 may be formed of a metal thin film. The patterning slit sheet 150 is fixed to the frame 150 such that a tensile force is exerted thereon. The patterning slits 151 may be formed by etching the patterning slit sheet 150 into a stripe pattern.

In the thin film deposition assembly 100 according to the current embodiment of the present invention, the total number of patterning slits 151 may be greater than the total number of deposition source nozzles 121. In addition, there may be a greater number of patterning slits 151 than deposition source nozzles 121 disposed between two adjacent barrier plates 131. The number of patterning slits 151 may be equal to the number of deposition patterns to be formed on the substrate 500.

In addition, the barrier plate assembly 130 and the patterning slit sheet 150 may be disposed to be spaced apart from each other by a predetermined distance. Alternatively, the barrier plate assembly 130 and the patterning slit sheet 150 may be connected by a second connection member 133. The temperature of the barrier plate assembly 130 may increase to 100° C. or higher due to the deposition source 110 whose temperature is high. Thus, in order to prevent the heat of the barrier plate assembly 130 from being conducted to the patterning slit sheet 150, the barrier plate assembly 130 and the patterning slit sheet 150 may be separated from each other by a predetermined distance.

As described above, the thin film deposition assembly 100 according to the current embodiment of the present invention performs deposition while the thin film deposition assembly 100 or the substrate 500 is moved relative to the other. In order to move the thin film deposition assembly 100 relative to the substrate 500, the patterning slit sheet 150 is spaced apart from the substrate 500 by a predetermined distance. In addition, in order to prevent the formation of a relatively large shadow zone on the substrate 500 when the patterning slit sheet 150 and the substrate 500 are spaced from each other, the barrier plates 131 are arranged between the deposition source nozzle unit 120 and the patterning slit sheet 150 to force the deposition material 115 to move in a straight direction. Thus, the size of the shadow zone that may be formed on the substrate 500 is sharply reduced.

In a conventional deposition method using an FMM, deposition is performed with the FMM in close contact with a substrate in order to prevent formation of a shadow zone on the substrate. However, when the FMM is used in close contact with the substrate, the contact may cause defects, such as scratches on patterns formed on the substrate. In addition, in the conventional deposition method, the size of the mask has to be the same as the size of the substrate since the mask cannot be moved relative to the substrate. Thus, the size of the mask has to be increased as display devices become larger. However, it is not easy to manufacture such a large mask.

In order to overcome this problem, in the thin film deposition assembly 100 according to the current embodiment of the present invention, the patterning slit sheet 150 is disposed to be spaced apart from the substrate 500 by a predetermined distance. The formation of a desirable deposition pattern may be facilitated by installing the barrier plates 131 to reduce the size of the shadow zone formed on the substrate 500.

As described above, when the patterning slit sheet 150 is manufactured to be smaller than the substrate 500, the patterning slit sheet 150 may be moved relative to the substrate 500 during deposition. Thus, it is no longer necessary to manufacture a large FMM as used in the conventional deposition method. In addition, since the substrate 500 and the patterning slit sheet 150 are spaced apart from each other, defects caused due to contact therebetween may be prevented. In addition, since it is unnecessary to contact the substrate 500 with the patterning slit sheet 150 during a deposition process, the manufacturing speed may be improved.

As shown in FIG. 12, the thin film deposition assembly 100 may also include one or more alignment devices 170 and one or more alignment targets 159 that assist in alignment of the patterning slit sheet 150 with respect to the substrate 100.

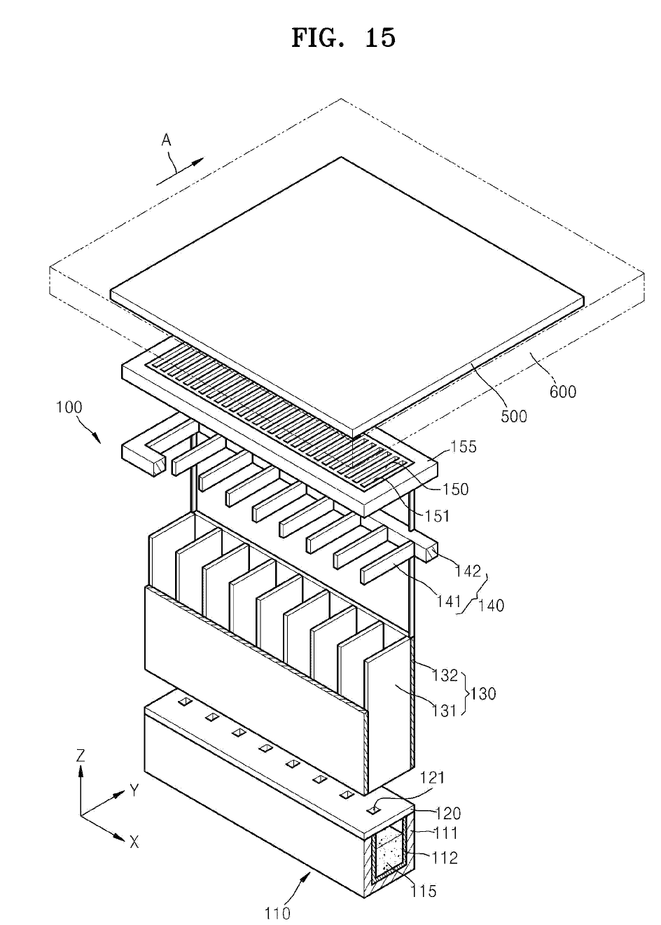

FIG. 15 is a schematic perspective view of a modified example of the thin film deposition assembly 100 of FIG. 12.

Referring to FIG. 15, the thin film deposition assembly 100 according to the current embodiment includes a deposition source 110, a deposition source nozzle unit 120, a first barrier plate assembly 130, a second barrier plate assembly 140, and a patterning slit sheet 150.

Although a chamber is not illustrated in FIG. 15 for convenience of explanation, all the components of the thin film deposition assembly 100 may be disposed within a chamber that is maintained at an appropriate degree of vacuum. The chamber is maintained at an appropriate vacuum in order to allow a deposition material to move in a substantially straight line through the thin film deposition assembly 100.

The substrate 500, which constitutes a target on which a deposition material 115 is to be deposited, is disposed in the chamber. The deposition source 115 that contains and heats the deposition material 115 is disposed in an opposite side of the chamber to the side in which the substrate 500 is disposed.

Detailed structures of the deposition source 110 and the patterning slit sheet 150 are the same as those of FIG. 12 and thus, detailed descriptions thereof will not be repeated here. The first barrier plate assembly 130 is the same the barrier plate assembly 130 of FIG. 4 and thus, a detailed description thereof will not be repeated here.

The second barrier plate assembly 140 is disposed at a side of the first barrier plate assembly 130. The second barrier plate assembly 140 includes a plurality of second barrier plates 141 and a second barrier plate frame 141 that constitutes an outer plate of the second barrier plates 142.

The plurality of second barrier plates 141 may be arranged parallel to each other at equal intervals in the X-axis direction. In addition, each of the second barrier plates 141 may be formed to extend in the YZ plane in FIG. 11, i.e., perpendicular to the X-axis direction.

The plurality of first barrier plates 131 and second barrier plates 141 arranged as described above partition the space between the deposition source nozzle unit 120 and the patterning slit sheet 150. The deposition space is divided by the first barrier plates 131 and the second barrier plates 141 into sub-deposition spaces that respectively correspond to the deposition source nozzles 121 through which the deposition material 115 is discharged.

The second barrier plates 141 may be disposed to correspond to the first barrier plates 131. The second barrier plates 141 may be respectively disposed to be parallel to and to be on the same plane as the first barrier plates 131. Each pair of the corresponding first and second barrier plates 131 and 141 may be located on the same plane. Although the first barrier plates 131 and the second barrier plates 141 are respectively illustrated as having the same thickness in the Y-axis direction, aspects of the present invention are not limited thereto. The second barrier plates 141, which may be accurately aligned with the patterning slit sheet 151, may be formed to be relatively thin, whereas the first barrier plates 131, which do not need to be precisely aligned with the patterning slit sheet 151, may be formed to be relatively thick. This makes it easier to manufacture the thin film deposition assembly 100.

As illustrated in FIG. 1, a plurality of thin film deposition assemblies, which each have the same structure as the thin film deposition assembly 100 described above with respect to FIGS. 12 and 15, may be successively disposed in the first chamber 731. In this case, the thin film deposition assemblies 100, 200, 300 and 400 may be used to deposit different deposition materials, respectively. For example, the thin film deposition assemblies 100, 200, 300 and 400 may have different patterning slit patterns, so that pixels of different colors, for example, red, green and blue, may be simultaneously defined through a film deposition process. Moreover, the thin film deposition assemblies 100, 200, 300, 400 may be located in a single deposition chamber 731 as shown in FIG. 1 or in separate deposition chambers 731 and 732 housed in a single deposition unit 730 as shown in FIG. 2 through which a circulating unit 610 conveys an electrostatic chuck 600 to which a substrate 500 is affixed.

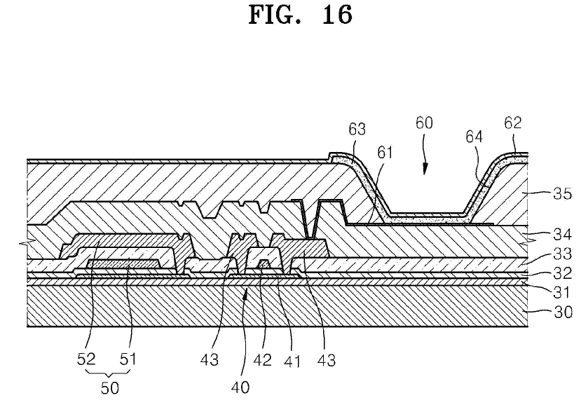

FIG. 16 is a cross-sectional view of an active matrix organic light-emitting display device fabricated by using a thin film deposition apparatus, according to an embodiment of the present invention. It is to be understood that where is stated herein that one layer is “formed on” or “disposed on” a second layer, the first layer may be formed or disposed directly on the second layer or there may be intervening layers between the first layer and the second layer. Further, as used herein, the term “formed on” is used with the same meaning as “located on” or “disposed on” and is not meant to be limiting regarding any particular fabrication process.

Referring to FIG. 16, the active matrix organic light-emitting display device according to the current embodiment is formed on a substrate 30. The substrate 30 may be formed of a transparent material, such as, for example, glass, plastic or metal. An insulating layer 31, such as a buffer layer, is formed on an entire surface of the substrate 30.

A thin film transistor (TFT) 40, a capacitor 50, and an organic light-emitting diode (OLED) 60 are disposed on the insulating layer 31, as illustrated in FIG. 16.

A semiconductor active layer 41 is formed on an upper surface of the insulating layer 31 in a predetermined pattern. A gate insulating layer 32 is formed to cover the semiconductor active layer 41. The semiconductor active layer 41 may include a p-type or n-type semiconductor material.

A gate electrode 42 of the TFT 40 is formed in a region of the gate insulating layer 32 corresponding to the semiconductor active layer 41. An interlayer insulating layer 33 is formed to cover the gate electrode 42. The interlayer insulating layer 33 and the gate insulating layer 32 are etched by, for example, dry etching, to form a contact hole exposing parts of the semiconductor active layer 41.

A source/drain electrode 43 is formed on the interlayer insulating layer 33 to contact the semiconductor active layer 41 through the contact hole. A passivation layer 34 is formed to cover the source/drain electrode 43, and is etched to expose a part of the drain electrode 43. An insulating layer (not shown) may be further formed on the passivation layer 34 so as to planarize the passivation layer 34.

In addition, the OLED 60 displays predetermined image information by emitting red, green, or blue light according to a flow of current. The OLED 60 includes a first electrode 61 disposed on the passivation layer 34. The first electrode 61 is electrically connected to the drain electrode 43 of the TFT 40.

A pixel defining layer 35 is formed to cover the first electrode 61. An opening 64 is formed in the pixel defining layer 35, and an organic light-emitting layer 63 is formed in a region defined by the opening 64. A second electrode 62 is formed on the organic light-emitting layer 63.

The pixel defining layer 35, which defines individual pixels, is formed of an organic material. The pixel defining layer 35 also planarizes the surface of a region of the substrate 30 in which the first electrode 61 is formed, and in particular, the surface of the passivation layer 34.

The first electrode 61 and the second electrode 62 are insulated from each other, and respectively apply voltages of opposite polarities to the organic light-emitting layer 63 to induce light emission.

The organic light-emitting layer 63 may be formed of a low-molecular weight organic material or a high-molecular weight organic material. When a low-molecular weight organic material is used, the organic light-emitting layer 63 may have a single or multi-layer structure including at least one selected from the group consisting of a hole injection layer (HIL), a hole transport layer (HTL), an emission layer (EML), an electron transport layer (ETL), and an electron injection layer (EIL). Examples of available organic materials may include copper phthalocyanine (CuPc), N,N′-di(naphthalene-1-yl)-N,N′-diphenyl-benzidine (NPB), tris-8-hydroxyquinoline aluminum (Alq3), and the like.

An organic light-emitting layer 63 containing such low-molecular weight organic materials may be formed by depositing organic materials by vacuum deposition using one of the thin film deposition apparatuses described above with reference to FIGS. 1 through 15. After the opening 64 is formed in the pixel defining layer 35, the substrate 30 is transferred to the first chamber 731, as illustrated in FIG. 1 or 2 (the substrate 30 is FIG. 16 may be a substrate 500 as shown in FIGS. 1 and 2). Target organic materials are deposited by the first to forth thin film deposition assemblies 100 to 400.

After the organic light-emitting layer 63 is formed, the second electrode 62 may be formed by the same deposition method as used to form the organic light-emitting layer 63.

The first electrode 61 may function as an anode, and the second electrode 62 may function as a cathode. Alternatively, the first electrode 61 may function as a cathode, and the second electrode 62 may function as an anode. The first electrode 61 may be patterned to correspond to individual pixel regions, and the second electrode 62 may be formed to cover all the pixels.

The first electrode 61 may be formed as a transparent electrode or a reflective electrode. A transparent electrode may be formed of indium tin oxide (ITO), indium zinc oxide (IZO), zinc oxide (ZnO), or indium oxide (In₂O₃). A reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃ on the reflective layer. The first electrode 61 may be formed by forming a layer by, for example, sputtering, and then patterning the layer by, for example, photolithography.

The second electrode 62 may also be formed as a transparent electrode or a reflective electrode. When the second electrode 62 is formed as a transparent electrode, the second electrode 62 functions as a cathode. To this end, such a transparent electrode may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), or a compound thereof on a surface of the organic light-emitting layer 63 and forming an auxiliary electrode layer or a bus electrode line thereon from ITO, IZO, ZnO, In₂O₃, or the like. When the second electrode 62 is formed as a reflective electrode, the reflective layer may be formed by depositing Li, Ca, LiF/Ca, LiF/Al, Al, Ag, Mg, or a compound thereof on the entire surface of the organic light-emitting layer 63. The second electrode 62 may be formed by using the same deposition method as used to form the organic light-emitting layer 63 described above.

The thin film deposition apparatuses according to the embodiments of the present invention described above may be applied to form an organic layer or an inorganic layer of an organic TFT, and to form layers from various materials.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film deposition apparatus comprising:
an electrostatic chuck comprising a body that contacts a substrate that constitutes a deposition target and that includes a supporting surface that fixedly engages the substrate by an electrostatic force, an electrode installed in the body to generate the electrostatic force on the supporting surface, and a battery that is electrically connected to the electrode in the body;
a plurality of chambers that are maintained in vacuum states;
at least one thin film deposition assembly disposed in one of the plurality of chambers, separated by a predetermined distance from the substrate, and positioned to form a thin film on the substrate supported by the electrostatic chuck; and
a carrier that moves the electrostatic chuck through the chambers.

2. The thin film deposition apparatus of claim 1, wherein the battery is formed in the body.

3. The thin film deposition apparatus of claim 1, wherein the carrier comprises:
a support that extends through the chambers;
a movement bar that engages the support and that supports edges of the electrostatic chuck; and
a driving unit disposed between the support and the movement bar to move the movement bar along the support.

4. The thin film deposition apparatus of claim 1, wherein the thin film deposition assembly comprises:
a deposition source that discharges a deposition material;
a deposition source nozzle unit disposed at a side of the deposition source and including a plurality of deposition source nozzles arranged in a first direction; and
a patterning slit sheet disposed opposite to and spaced apart from the deposition source nozzle unit and including a plurality of patterning slits arranged in a second direction perpendicular to the first direction,
wherein deposition is performed while the substrate or the thin film deposition assembly is moved relative to the other in the first direction, and
the deposition source, the deposition source nozzle unit, and the patterning slit sheet are integrally formed as one body.

5. The thin film deposition apparatus of claim 4, wherein the deposition source and the deposition source nozzle unit, and the patterning slit sheet are integrally connected as one body by a connection member that guides flow of the deposition material.

6. The thin film deposition apparatus of claim 5, wherein the connection member seals a space between the deposition source nozzle unit disposed at the side of the deposition source, and the patterning slit sheet.

7. The thin film deposition apparatus of claim 4, wherein the plurality of deposition source nozzles are tilted at a predetermined angle.

8. The thin film deposition apparatus of claim 7, wherein the plurality of deposition source nozzles include deposition source nozzles arranged in two rows disposed in the first direction, and wherein each of the deposition source nozzles in each of the two rows is tilted at the predetermined angle toward a corresponding deposition source nozzle of the other of the two rows.

9. The thin film deposition apparatus of claim 7, wherein the plurality of deposition source nozzles include deposition source nozzles arranged in two rows disposed in the first direction,
the deposition source nozzles of a row located at a first side of the patterning slit sheet are arranged to face a second side of the patterning slit sheet, and
the deposition source nozzles of the other row located at the second side of the patterning slit sheet are arranged to face the first side of the patterning slit sheet.

10. The thin film deposition apparatus of claim 1, wherein the thin film deposition assembly comprises:
a deposition source that discharges a deposition material;
a deposition source nozzle unit disposed at a side of the deposition source and including a plurality of deposition source nozzles arranged in a first direction;
a patterning slit sheet disposed opposite to the deposition source nozzle unit and including a plurality of patterning slits arranged in the first direction; and
a barrier plate assembly comprising a plurality of barrier plates that are disposed between the deposition source nozzle unit and the patterning slit sheet in the first direction, and partition a space between the deposition source nozzle unit and the patterning slit sheet into a plurality of sub-deposition spaces, and
wherein the thin film deposition assembly is spaced apart from the substrate, and the thin film deposition assembly or the substrate fixedly engaged onto the electrostatic chuck is moved relative to the other.

11. The thin film deposition apparatus of claim 10, wherein the plurality of barrier plates extend in a second direction substantially perpendicular to the first direction.

12. The thin film deposition apparatus of claim 10, wherein the barrier plate assembly comprises a first barrier plate assembly comprising a plurality of first barrier plates, and a second barrier plate assembly comprising a plurality of second barrier plates.

13. The thin film deposition apparatus of claim 12, wherein each of the first barrier plates and each of the second barrier plates extend in a second direction substantially perpendicular to the first direction.

14. The thin film deposition apparatus of claim 13, wherein the first barrier plates are arranged to respectively correspond to the second barrier plates.

15. The thin film deposition apparatus of claim 10, wherein the deposition source and the barrier plate assembly are spaced apart from each other.

16. The thin film deposition apparatus of claim 10, wherein the barrier plate assembly and the patterning slit sheet are spaced apart from each other.

17. A method of manufacturing an organic light emitting display device, the method comprising:
fixing a substrate that constitutes a deposition target onto an electrostatic chuck, wherein the electrostatic chuck comprises a body that contacts the substrate and that includes a supporting surface that fixedly engages the substrate by an electrostatic force, an electrode installed in the body to generate the electrostatic force on the supporting surface, and a battery that is electrically connected to the electrode in the body;
transferring the electrostatic chuck on which the substrate is fixedly engaged through a plurality of chambers that are maintained in a vacuum state; and
forming an organic layer on the substrate by depositing a deposition material from a thin film deposition assembly disposed in at least one of the chambers, wherein the electrostatic chuck on which the substrate is disposed or the thin film deposition assembly is moved relative to the other.

18. The method of claim 17, wherein the battery is formed in the body.

19. The method of claim 17, wherein the thin film deposition assembly comprises:
a deposition source that discharges the deposition material;
a deposition source nozzle unit disposed at a side of the deposition source and including a plurality of deposition source nozzles arranged in a first direction; and
a patterning slit sheet disposed opposite to and spaced apart from the deposition source nozzle unit and including a plurality of patterning slits arranged in a second direction perpendicular to the first direction,
wherein the deposition source, the deposition source nozzle unit, and the patterning slit sheet are integrally formed as one body,
the thin film deposition assembly is spaced apart from the substrate, and
the depositing of the deposition material is performed while the substrate or the thin film deposition assembly is moved relative to the other in the first direction.

20. The method of claim 17, wherein the thin film deposition assembly comprises:
a deposition source that discharges the deposition material;
a deposition source nozzle unit disposed at a side of the deposition source and including a plurality of deposition source nozzles arranged in a first direction;
a patterning slit sheet disposed opposite to and spaced apart from the deposition source nozzle unit and including a plurality of patterning slits arranged in the first direction; and
a barrier plate assembly comprising a plurality of barrier plates that are disposed between the deposition source nozzle unit and the patterning slit sheet in the first direction, and that partition a space between the deposition source nozzle unit and the patterning slit sheet into a plurality of sub-deposition spaces,
wherein the thin film deposition assembly spaced apart from the substrate, and the depositing of the deposition material is performed while the substrate or the thin film deposition assembly is moved relative to the other.

21. A thin film deposition apparatus comprising:
a loading unit that fixes a substrate on which a deposition material is to be deposited onto an electrostatic chuck, wherein the electrostatic chuck comprises a body that contacts the substrate and that includes a supporting surface that fixedly engages the substrate by an electrostatic force, an electrode installed in the body to generate the electrostatic force on the supporting surface, and a battery that is electrically connected to the electrode in the body;
a deposition unit comprising one or more chambers and at least one thin film deposition assembly disposed in the one or more chambers to deposit a deposition material on the substrate fixed on the electrostatic chuck;
an unloading unit that removes the substrate on which deposition has been performed from the electrostatic chuck;
a first circulating unit including a first carrier that sequentially moves the electrostatic chuck from the loading unit through the one or more chambers of the deposition unit, and from the deposition unit to the unloading unit; and
a second circulating unit including a second carrier that returns the electrostatic chuck from which the substrate has been removed by the unloading unit, to the loading unit.

22. The thin film deposition apparatus of claim 21, wherein the battery is formed in the body.

23. The thin film deposition apparatus of claim 21, wherein the first carrier comprises:
a support that extends through the one or more chambers;
a movement bar that engages the support and that supports edges of the electrostatic chuck; and
a driving unit disposed between the support and the movement bar to move the movement bar along the support.

24. The thin film deposition apparatus of claim 21, wherein the second carrier comprises:
a support that extends between the unloading unit the loading unit at an exterior of the deposition unit;
a movement bar that engages the support and that supports edges of the electrostatic chuck; and
a driving unit disposed between the support and the movement bar to move the movement bar along the support.
